(19) United States
(12) Patent Application Publication
(10) Pub. No.: US 2020/0218027 A1
(43) Pub. Date: Jul. 9, 2020

(54) PHOTOSENSITIVE CHIP, LENS MODULE HAVING THE PHOTOSENSITIVE CHIP AND ELECTRONIC DEVICE HAVING THE LENS MODULE

(71) Applicant: TRIPLE WIN TECHNOLOGY(SHENZHEN) CO.LTD., Shenzhen (CN)

(72) Inventors: SHIN-WEN CHEN, Tu-Cheng (TW); JIAN-CHAO SONG, Shenzhen (CN); SHENG-JIE DING, Shenzhen (CN); JING-WEI LI, Shenzhen (CN)

(21) Appl. No.: 16/390,134

(22) Filed: Apr. 22, 2019

(30) Foreign Application Priority Data
Jan. 9, 2019 (CN) 201910020744.2

(51) Int. Cl. G02B 7/02; H05K 1/02; G02B 13/18; G02B 7/00

(52) U.S. Cl. CPC G02B 7/02; H05K 1/028; H05K 1/181; G02B 7/006; H05K 2201/10121; G02B 13/18

(57) ABSTRACT

A photosensitive chip includes a photosensitive region, a non-photosensitive region and an adhesive layer. The non-photosensitive region protrudes from a periphery of the photosensitive region to surround the photosensitive region. The adhesive layer covers the non-photosensitive region to absorb light and reduce an intensity of light reflected from the adhesive layer. The disclosure also provides a lens module having the photosensitive chip, and an electronic device having the lens module.

### FIELD

The subject matter herein generally relates to a photosensitive chip, a lens module having the photosensitive chip, and an electronic device having the lens module.

### BACKGROUND

When lens module works, stray light formed in the lens module affects a quality of imaging. In order to avoid the stray light, ink is usually applied on an edge of the filter. However, in order to improve the light blocking effect, it is usually necessary to increase the range of the ink. A production cost of the lens module is increased, and a vignetting appears in the lens module to reduce an imaging quality of the lens module.

### BRIEF DESCRIPTION OF THE DRAWINGS

Implementations of the present disclosure will now be described, by way of embodiments, with reference to the attached figures.

FIG. 1 is a diagram of an embodiment of a lens module.

FIG. 2 is an exploded, diagrammatic view of the lens module of FIG. 1.

FIG. 3 is exploded, diagrammatic view of the lens module of FIG. 1.

FIG. 4 is a cross-sectional view of the lens module taken along IV-IV line of FIG. 1 viewed from another angle.

FIG. 5 is diagram of an embodiment of an electronic device having the lens module of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

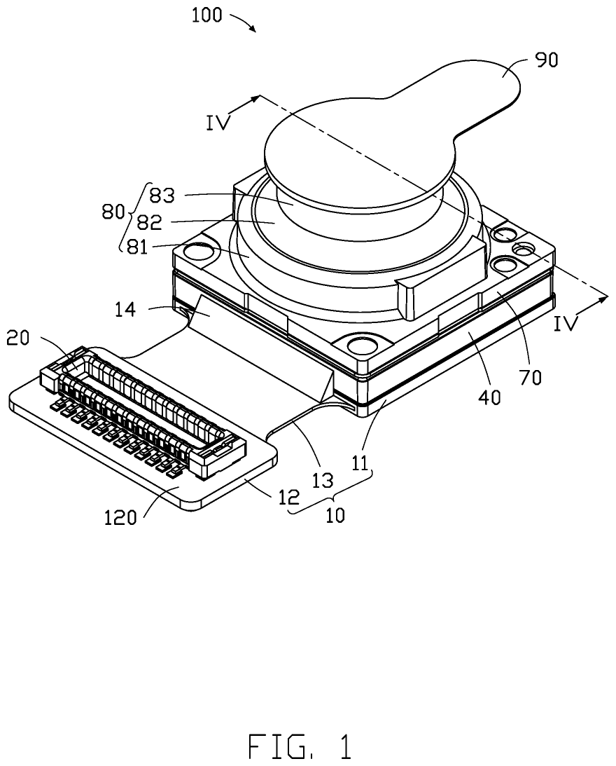

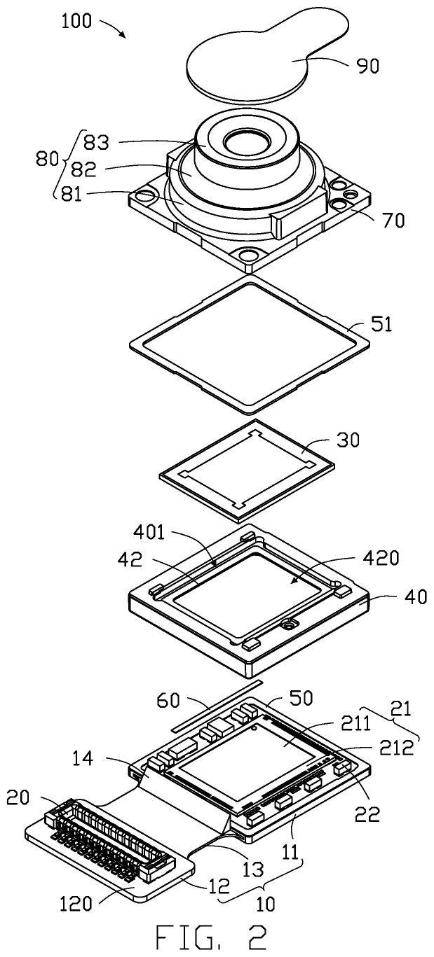

FIG. 1 illustrates an embodiment of a lens module 100. The lens module 100 includes a circuit board 10, a filter 30 (shown in FIG. 2), a base 40, a lens holder 70 and a lens 80.

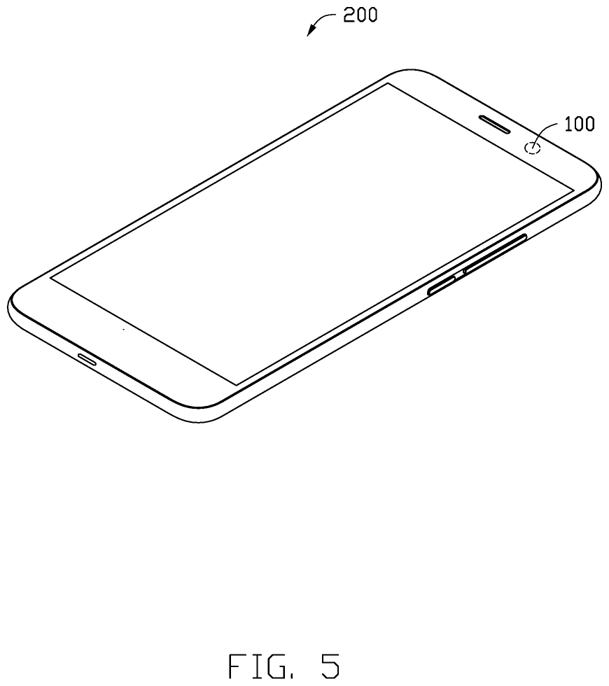

In at least one embodiment, the circuit board 10 may be a flexible circuit board, a rigid circuit board, or a rigid-flexible circuit board. In an embodiment, the circuit board 10 is a rigid-flexible circuit board including a first rigid portion 11, a second rigid portion 12, a flexible portion 13 connecting the first rigid portion 11 and the second rigid portion 12. An electronic connecting element 20 is mounted on a surface 120 of the second rigid portion 12. When the lens module 100 is applied to an electronic device 200 (shown in FIG. 5), the electronic connecting element 20 is configured to transmit signals between the lens module 100 and other components of the electronic device. In at least one embodiment, the electronic connecting element 20 may be a connector or a gold finger.

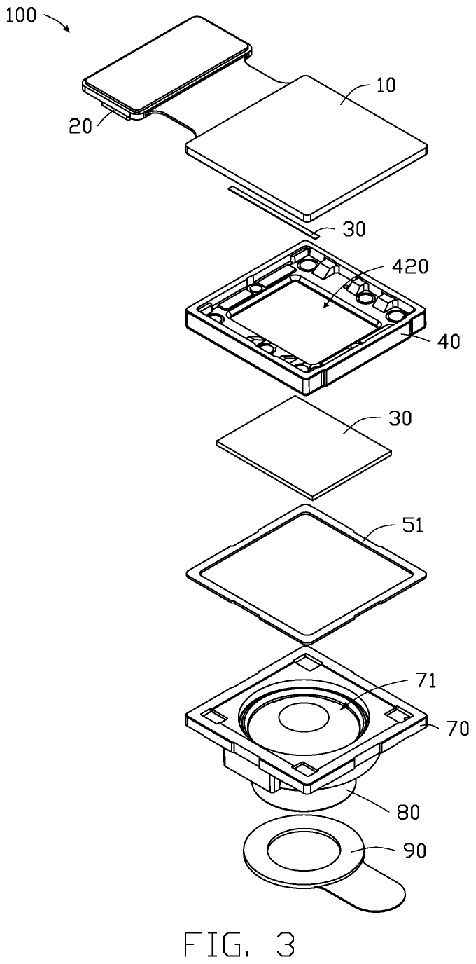

Referring to FIGS. 2 and 3, a photosensitive chip 21 and a plurality of electronic elements 22 are mounted on a surface 110 of the first rigid portion 11. In at least one embodiment, the photosensitive chip 21, the plurality of electronic elements 22 and the electronic connecting element 20 are mounted on a same surface of the circuit board 10. The electronic elements 22 may be at least one of resistors, capacitors, diodes, triodes, relays and electrically erasable programmable read-only memory (EEPROM).

The base 40 is mounted on the surface 110 of the first rigid portion 11 by a first adhesive layer 50. The photosensitive chip 21 and the electronic elements 22 are between the base 40 and the circuit board 10. In at least one embodiment, the base 40 may be generally cuboid. A through hole 41 is defined on the base 40 to correspond the photosensitive chip 21. In at least one embodiment, the through hole 41 may be generally rectangular. The base 40 includes an inner surface 401 surrounding to define the through hole 41. An annular protruding portion 42 extends from the inner surface 401 toward a central axis of the through hole 41, and surrounds to define a light passing hole 420.

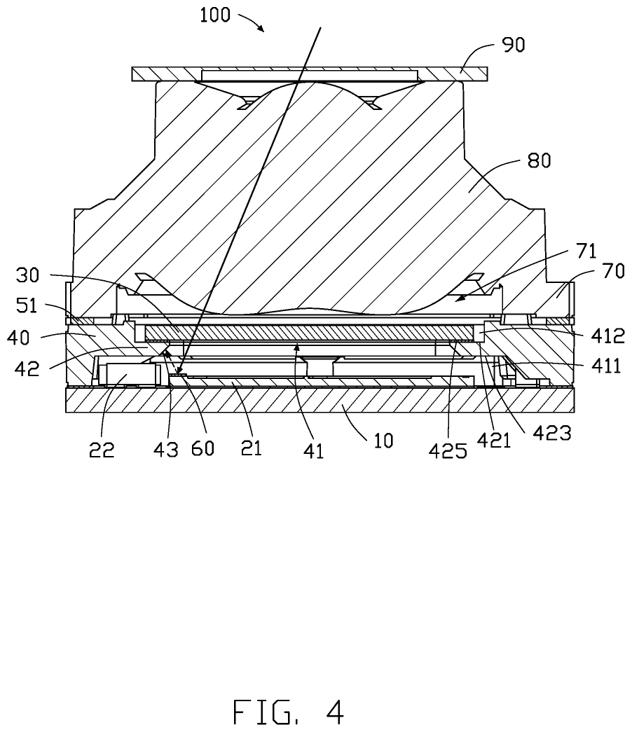

Referring to FIG. 4, the through hole 41 is separated by the annular protruding portion 42 to define a first receiving space 411 and a second receiving space 412. The photosensitive chip 21 is received in the first receiving space 411.

The photosensitive chip 21 includes a photosensitive region 211 and a non-photosensitive region 212 protruding from a periphery of the photosensitive region 211 to surround the photosensitive region 211. A size of the photosensitive region 211 is less than or equal to a size of the light passing hole 420, and the whole photosensitive region 211 corresponds to the light passing hole 420.

In at least one embodiment, the annular protruding portion 42 includes an upper surface 421, a connecting surface 425, a reflective surface 43 and a lower surface 423, connecting the supper surface 421 connecting in the order written. The connecting surface 425 surrounds to define the light passing hole 420. The reflective surface 43 slants toward the photosensitive chip 21.

An adhesive layer 60 covers on a surface of the non-photosensitive region 212 facing the annular protruding portion 42. The adhesive layer 60 can absorb light and reduce an intensity of light reflected from the adhesive layer.

In at least one embodiment, the adhesive layer 60 may cover the whole non-photosensitive region 212.

The filter 30 is received in the second receiving space 412 and mounted on the annular protruding portion 42 to cover the light passing hole 420. When light from outside pass through the filter and irradiate on the adhesive layer 60, the adhesive layer 60 can absorb some of the light to reduce an intensity of light reflected from the adhesive layer, thereby preventing the photosensitive chip 21 from forming stray light. Optical performances of the lens module 100 can be improved.

The lens module 100 may further includes a reinforcing glue layer 14 formed on the flexible portion 13. In at least one embodiment, the reinforcing glue layer 14, the photosensitive chip 21, the plurality of electronic elements 22 and the electronic connecting element 20 are mounted on a same surface of the circuit board 10. The reinforcing glue layer 14 can improve a mechanical strength of the circuit board 10.

In at least one embodiment, the lens holder 70 is mounted on the base 40 by a second adhesive layer 51. A receiving hole 71 is defined on the lens holder 70. The lens holder 70 may be made of metal or plastic. In at least one embodiment, the lens holder may be made of aluminum alloy.

The lens 80 is received in the receiving hole 71 and mounted on the lens holder 70. The lens 80 includes a first lens portion 81, a second lens portion 82 and a third portion 83. The second lens portion 82 is located between the first lens portion 81 and the third lens portion 83. A diameter of the second lens portion 82 is less than a diameter of the first lens portion 81, and a diameter of the third lens portion 83 is less than the diameter of the second lens portion 82.

In at least one embodiment, the lens module 100 may further include a protective part 90. The protective part 90 covers an end of the third lens portion 93 facing away from the photosensitive chip 21 to prevent dust from contaminating the lens 80.

Referring to FIG. 5, the lens module 100 can be used in an electronic device 200. The electronic device 200 can be a mobile phone, a laptop, a camera or others.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A photosensitive chip comprising:
a photosensitive region;
a non-photosensitive region; and
an adhesive layer;
wherein the non-photosensitive region protrudes from a periphery of the photosensitive region to surround the photosensitive region, the adhesive layer covers the non-photosensitive region to absorb light and reduce an intensity of light reflected from the adhesive layer.

2. A lens module comprising:
a base comprising:
a through hole; and
an annular protruding portion extending from an inner surface surrounding to define the through hole toward a central axis of the through hole; and
a photosensitive chip received in the through hole;
wherein the annular protruding portion separates the through hole to define a first receiving space and a second receiving space, the photosensitive chip received in the first receiving space, the annular protruding portion comprises a light passing hole and a reflective surface, the reflective surface is adjacent to the light passing hole and slants toward the photosensitive chip, the photosensitive chip comprises a photosensitive region corresponding to the light passing hole and a non-photosensitive region protruding from a periphery of the photosensitive region to surround the photosensitive region, an adhesive layer covers a surface of the non-photosensitive region facing the annular protruding portion to absorb light and reduce an intensity of light reflected from the adhesive layer.

3. The lens module of claim 2, wherein the lens module further comprises a circuit board, the base and the photosensitive chip are mounted on the circuit board, the base cooperates with the circuit board to receive the photosensitive chip.

4. The lens module of claim 3, wherein the circuit board comprises a first rigid portion, a second rigid portion, a flexible portion connecting the first rigid portion and the second rigid portion, the base and the photosensitive chip are mounted on the first rigid portion.

5. The lens module of claim 4, wherein the lens module further comprises an electronic connecting element, the electronic connecting element mounted on the second rigid portion to transmit signals.

6. The lens module of claim 4, wherein the base is mounted on the first rigid portion a first adhesive layer.

7. The lens module of claim 2, wherein the lens module further comprises a filter, the filter is received in the second receiving space and mounted on the annular protruding portion to cover the light passing hole.

8. The lens module of claim 2, wherein the lens module further comprises a lens holder and a lens, the lens holder is mounted on the base by a second adhesive layer, the lens holder defines a receiving hole, the lens is received in the receiving hole.

9. The lens module of claim 8, wherein the lens comprises a first lens portion, a second lens portion and a third lens portion, the second lens portion is located between the first lens portion and the third lens portion, a diameter of the second lens portion is less than a diameter of the first lens portion, and a diameter of the third lens portion is less than the diameter of the second lens portion.

10. The lens module of claim 9, wherein the lens module further comprises a protective part, the protective part covers an end of the third lens portion facing away from the photosensitive chip.

11. An electronic device comprising:
a lens module comprising:
a base comprising:
a through hole; and
an annular protruding portion extending from an inner surface surrounding to define the through hole toward a central axis of the through hole; and
a photosensitive chip received in the through hole;
wherein the annular protruding portion separates the through hole to define a first receiving space and a second receiving space, the photosensitive chip received in the first receiving space, the annular protruding portion comprises a light passing hole and a reflective surface, the reflective surface is adjacent to the light passing hole and slants toward the photosensitive chip, the photosensitive chip comprises a photosensitive region corresponding to the light passing hole and a non-photosensitive region protruding from a periphery of the photosensitive region to surround the photosensitive region, an adhesive layer covers a surface of the non-photosensitive region facing the annular protruding portion to absorb light and reduce an intensity of light reflected from the adhesive layer.

12. The electronic device of claim 11, wherein the lens module further comprises a circuit board, the base and the photosensitive chip are mounted on the circuit board, the base cooperates with the circuit board to receive the photosensitive chip.

13. The electronic device of claim 12, wherein the circuit board comprises a first rigid portion, a second rigid portion, a flexible portion connecting the first rigid portion and the second rigid portion, the base and the photosensitive chip are mounted on the first rigid portion.

14. The electronic device of claim 13, wherein the lens module further comprises an electronic connecting element, the electronic connecting element mounted on the second rigid portion to transmit signals.

15. The electronic device of claim 13, wherein the base is mounted on the first rigid portion a first adhesive layer.

16. The electronic device of claim 11, wherein the lens module further comprises a filter, the filter is received in the second receiving space and mounted on the annular protruding portion to cover the light passing hole.

17. The electronic device of claim 11, wherein the lens module further comprises a lens holder and a lens, the lens holder is mounted on the base by a second adhesive layer, the lens holder defines a receiving hole, the lens is received in the receiving hole.

18. The electronic device of claim 17, wherein the lens comprises a first lens portion, a second lens portion and a third lens portion, the second lens portion is located between the first lens portion and the third lens portion, a diameter of the second lens portion is less than a diameter of the first lens portion, and a diameter of the third lens portion is less than the diameter of the second lens portion.

19. The electronic device of claim 18, wherein the lens module further comprises a protective part, the protective part covers an end of the third lens portion facing away from the photosensitive chip.
